(19) United States
(12) Patent Application Publication
(10) Pub. No.: US 2025/0301780 A1
(43) Pub. Date: Sep. 25, 2025

(54) FIELD-EFFECT-TRANSISTOR WITH COMPOSITE GATE AND SOURCE-DRAIN CUTS

(71) Applicant: International Business Machines Corporation, Armonk, NY (US)

(72) Inventors: Julien Frougier, Albany, NY (US); Ruilong Xie, Niskayuna, NY (US); Tao Li, Slingerlands, NY (US); Chanro Park, Clifton Park, NY (US); Min Gyu Sung, Latham, NY (US); Juntao Li, Cohoes, NY (US)

(21) Appl. No.: 18/610,663

(22) Filed: Mar. 20, 2024

(51) Int. Cl. H01L 27/092; H01L 21/8238; H01L 29/06; H01L 29/423; H01L 29/66; H01L 29/775

(52) U.S. Cl. CPC H10D 84/85; H10D 30/014; H10D 30/43; H10D 30/6735; H10D 62/121; H10D 84/0188; H10D 84/038

(57) ABSTRACT

A microelectronic structure that includes a first nanosheet transistor and a second nanosheet transistor. The first nanosheet transistor is directly adjacent to the second nanosheet transistor along the gate direction, where the first nanosheet transistor includes a first source/drain and the second nanosheet transistor includes a second source/drain. A dielectric pillar is located between the first nanosheet transistor and the second nanosheet transistor. A height of the dielectric pillar varies between a gate region and a source/drain region located between the first nanosheet transistor and the second nanosheet transistor. A dielectric cut connected to the dielectric pillar.

### BACKGROUND

The present invention generally relates to the field of microelectronics, and more particularly to separating the source/drain from each other.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate components for each device without defects.

### BRIEF SUMMARY

Additional aspects and/or advantages will be set forth in part in the description which follows and, in part, will be apparent from the description, or may be learned by practice of the invention.

A microelectronic structure that includes a first field-effect-transistor and a second field-effect-transistor. The first field-effect-transistor is directly adjacent to the second field-effect-transistor along the gate direction, where the first field-effect-transistor includes a first source/drain and the second field-effect-transistor includes a second source/drain. A dielectric pillar is located between the first field-effect-transistor and the second field-effect-transistor. The dielectric pillar is a continuous structure between a source/drain region and an adjacent gate region. A height of the dielectric pillar varies between the gate region and the source/drain region located between the first field-effect-transistor and the second field-effect-transistor. A dielectric cut connected to the dielectric pillar.

A microelectronic structure includes a first nanosheet transistor and a second nanosheet transistor. The first nanosheet transistor is directly adjacent to the second nanosheet transistor along the gate direction. The first nanosheet transistor includes a first source/drain and the second nanosheet transistor includes a second source/drain. A dielectric pillar located between the first nanosheet transistor and the second nanosheet transistor. The dielectric pillar includes a protrusion located in a gate region and a lower plateau located in a source/drain region, such that a height of the protrusion and a height of the lower plateau are different. A dielectric cut connected to the dielectric pillar. The dielectric cut includes a valley to wrap around the dielectric pillar protrusion.

A method includes the steps of forming a first field-effect-transistor and a second field-effect-transistor. The first field-effect-transistor is directly adjacent to the second field-effect-transistor along the gate direction, where the first field-effect-transistor includes a first source/drain and the second field-effect-transistor includes a second source/drain. Forming a dielectric pillar is located between the first field-effect-transistor and the second field-effect-transistor. The dielectric pillar is a continuous structure between a source/drain region and an adjacent gate region. A height of the dielectric pillar varies between the gate region and the source/drain region located between the first field-effect-transistor and the second field-effect-transistor. The height differences of the dielectric pillar are caused by the processing of the source/drain region. Forming dielectric cut connected to the dielectric pillar.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section X1 of the nanosheet transistor after the formation of the of the dummy gate, hardmask, gate spacers, and dielectric pillars, in accordance with the embodiment of the present invention.

FIG. 3 illustrates a cross section Y1 of the gate region after the formation of the of the dummy gate, hardmask, gate spacers, and dielectric pillars, in accordance with the embodiment of the present invention.

FIG. 4 illustrates a cross section Y2 of the source/drain region after the formation of the of the dummy gate, hardmask, gate spacers, and dielectric pillars, in accordance with the embodiment of the present invention.

FIG. 5 illustrates a cross section X1 of the nanosheet transistor after the formation of nanostacks and an inner spacer, in accordance with the embodiment of the present invention.

FIG. 6 illustrates a cross section Y2 of the source/drain region after the formation of nanostacks and an inner spacer, in accordance with the embodiment of the present invention.

FIG. 7 illustrates a cross section X1 of the nanosheet transistor after the formation of source/drains, in accordance with the embodiment of the present invention.

FIG. 8 illustrates a cross section Y2 of the source/drain region after the formation of source/drains, in accordance with the embodiment of the present invention.

FIG. 9 illustrates a cross section X1 of the nanosheet transistor after the formation of the interlayer dielectric layer, removal of the dummy gate and the hardmask, formation of the gate, formation of the gate cap, in accordance with the embodiment of the present invention.

FIG. 10 illustrates a cross section Y1 of the gate region after the formation of the interlayer dielectric layer, removal of the dummy gate and the hardmask, formation of the gate, formation of the gate cap, in accordance with the embodiment of the present invention.

FIG. 11 illustrates a cross section Y2 of the source/drain region after the formation of the interlayer dielectric layer, removal of the dummy gate and the hardmask, formation of the gate, formation of the gate cap, in accordance with the embodiment of the present invention.

FIG. 12 illustrates a cross section Y1 of the gate region after the first cut step, in accordance with the embodiment of the present invention.

FIG. 13 illustrates a cross section Y2 of the source/drain region after the first cut step, in accordance with the embodiment of the present invention.

FIG. 14 illustrates a cross section Y1 of the gate region after formation of a second lithography layer, and patterning second cut trenches, in accordance with the embodiment of the present invention.

FIG. 15 illustrates a cross section Y2 of the source/drain region after formation of a second lithography layer, and patterning second cut trenches, in accordance with the embodiment of the present invention.

FIG. 16 illustrates a cross section Y1 of the gate region after formation of the dielectric cuts, in accordance with the embodiment of the present invention.

FIG. 17 illustrates a cross section Y2 of the source/drain region after formation of the dielectric cuts, in accordance with the embodiment of the present invention.

FIG. 18 illustrates a cross section X1 of the nanosheet transistor after increasing the height of the interlayer dielectric layer and the formation of source/drain contacts and gate contacts, in accordance with the embodiment of the present invention.

FIG. 19 illustrates a cross section Y1 of the gate region after increasing the height of the interlayer dielectric layer and the formation of source/drain contacts and gate contacts, in accordance with the embodiment of the present invention.

FIG. 20 illustrates a cross section Y2 of the source/drain region after increasing the height of the interlayer dielectric layer and the formation of source/drain contacts and gate contacts, in accordance with the embodiment of the present invention.

FIG. 21 illustrates a cross section X1 of the nanosheet transistor after formation of the back-end-of-line (BEOL) layer, in accordance with the embodiment of the present invention.

FIG. 22 illustrates a cross section Y1 of the gate region after formation of the back-end-of-line (BEOL) layer, in accordance with the embodiment of the present invention.

FIG. 23 illustrates a cross section Y2 of the source/drain region after formation of the back-end-of-line (BEOL) layer, in accordance with the embodiment of the present invention.

FIG. 24 illustrates a cross section X2 of the dielectric cut A after formation of the back-end-of-line (BEOL) layer, in accordance with the embodiment of the present invention.

FIG. 25 illustrates a cross section X1 of the nanosheet transistor after formation of the backside-power-distribution-network, in accordance with the embodiment of the present invention.

FIG. 26 illustrates a cross section Y1 of the gate region after formation of the backside-power-distribution-network, in accordance with the embodiment of the present invention.

FIG. 27 illustrates a cross section Y2 of the source/drain region after formation of the backside-power-distribution-network, in accordance with the embodiment of the present invention.

FIG. 28 illustrates a cross section X2 of the dielectric cut A after formation of the backside-power-distribution-network, in accordance with the embodiment of the present invention.

FIG. 29 illustrates a cross section X1 of the nanosheet transistor after formation of the back-end-of-line (BEOL) layer, in accordance with the embodiment of the present invention.

FIG. 30 illustrates a cross section Y1 of the gate region after formation of the back-end-of-line (BEOL) layer, in accordance with the embodiment of the present invention.

FIG. 31 illustrates a cross section Y2 of the source/drain region after formation of the back-end-of-line (BEOL) layer, in accordance with the embodiment of the present invention.

FIG. 32 illustrates a cross section X2 of the dielectric cut A after formation of the back-end-of-line (BEOL) layer, in accordance with the embodiment of the present invention.

FIG. 33 illustrates a cross section X1 of the nanosheet transistor after formation of the back-end-of-line (BEOL) layer, in accordance with the embodiment of the present invention.

FIG. 34 illustrates a cross section Y1 of the gate region after formation of the back-end-of-line (BEOL) layer, in accordance with the embodiment of the present invention.

FIG. 35 illustrates a cross section Y2 of the source/drain region after formation of the back-end-of-line (BEOL) layer, in accordance with the embodiment of the present invention.

FIG. 36 illustrates a cross section X2 of the dielectric cut A after formation of the back-end-of-line (BEOL) layer, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards separating source/drains from each other. An initial dielectric pillar is formed prior to the formation of the source/drains, however during the downstream processing, the height of the dielectric pillar in the source/drain region is reduced. Since the height of the dielectric pillar has been reduced, then during the formation of the source/drains, adjacent source/drains will grow over, extend over, and/or could merge over the top of the dielectric pillars. This can lead to electrical defects caused by the adjacent source/drains being in contact with each other or in close proximity to each other. The present invention utilizes a two-stage cut process, where the first stage will create a gate cut that extends into the gate region and the source/drain region. The first stage or first cut will partial etch/cut the source/drain or remove layers located above the source/drain, but adjacent source/drains might not have this cut if an adjacent gate cut did not occur. This causes variances/differences within the source/drain region. A second cut or a source/drain cut will separate the source/drains from each other. The second cut will extend the cut made by the first cut downwards within source/drain region and can make additional source/drain cuts where an initial cut (i.e., the first cut) was not performed. The source/drain cut where there was an initial cut will cut deeper (or extends downwards to a lower depth) than a source/drain cut where an initial cut was not present. The source/drain cut exposes the dielectric pillar that were located between the source/drains allowing for a combination dielectric pillar to be formed. The combination dielectric pillar is composed of the remaining dielectric pillar (i.e., the dielectric pillar that height was reduced by the source/drain region processing) and the source/drain cut (i.e., the source/drain cut filled with a dielectric material). The dielectric pillar extends across the source/drain regions and the gate regions and has different dimensions (e.g., the height/thickness/depth) between the regions. For example, the height/dimension of the dielectric pillar is greater in the gate region than the source/drain region, thus giving the dielectric pillar protrusion profile in the gate regions. Furthermore, the cut pillars will have a larger dimension height/thickness/depth in the source/drain regions (which corresponds the reduced height of the dielectric pillar) when compared to the gate cut regions.

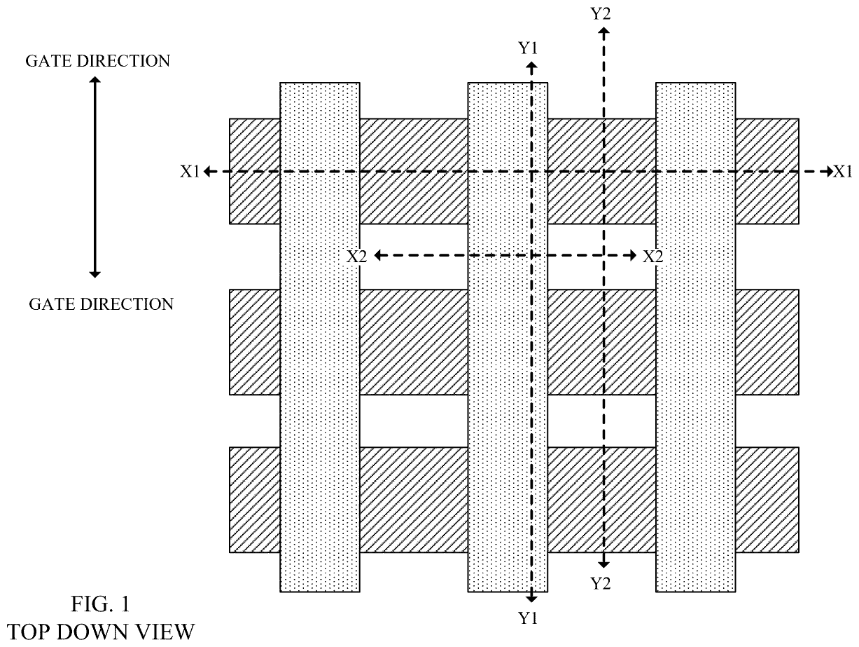

FIG. 1 illustrates a top-down view of multiple devices, in accordance with the embodiment of the present invention. The cross-section X1 extends horizontally through nanosheet transistors or field-effect-transistors. The cross-section X2 extends horizontally through a gate region and adjacent source/drain regions. Cross section Y1 is perpendicular to cross section X1, where cross section Y1 is through a gate region that spans across multiple adjacent nanosheet transistors or field-effect-transistors. Cross section Y2 is perpendicular to cross section X1, where cross section Y1 is through a source/drain region that spans across multiple adjacent nanosheet transistors or field-effect-transistors. Cross-section X1 and X2 are perpendicular to the gate direction and cross-section Y1 and Y2 are parallel to the gate direction.

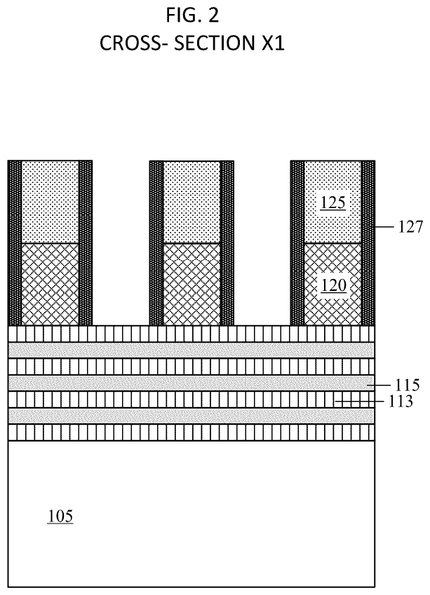

Referring now to FIGS. 2, 3 and 4, a structure is shown during an intermediate step of a method of fabricating after the formation of the dummy gate 120, hardmask 125, and gate spacer 127. FIG. 2 illustrates the nano stack of the nanosheet transistors that includes a substrate 105, a plurality of layers, a dummy gate 120, a hardmask 125, gate spacer 127, and dielectric pillars 133G, 133SD.

The plurality of layers includes alternating layers that includes channel layers 115 (e.g., nanosheets), and sacrificial layers 113. The plurality of channel layers 115 can be comprised of, for example, Si. The plurality of sacrificial layers 113 can be comprised of SiGe, where Ge is in the percentage of 15 to 35%. The substrate 105 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

A dummy gate 120 is formed on top of the alternating layers and a hardmask 125 is formed on top of the dummy gate 120. The dummy gate 120 and the hardmask are patterned to form a plurality of columns on top of the top layer of the alternating layers. Gate spacer 127 is formed on the exposed surfaces and etch back so that gate spacer 127 is located on the vertical sidewalls of the dummy gate 120 and hardmask 127 columns.

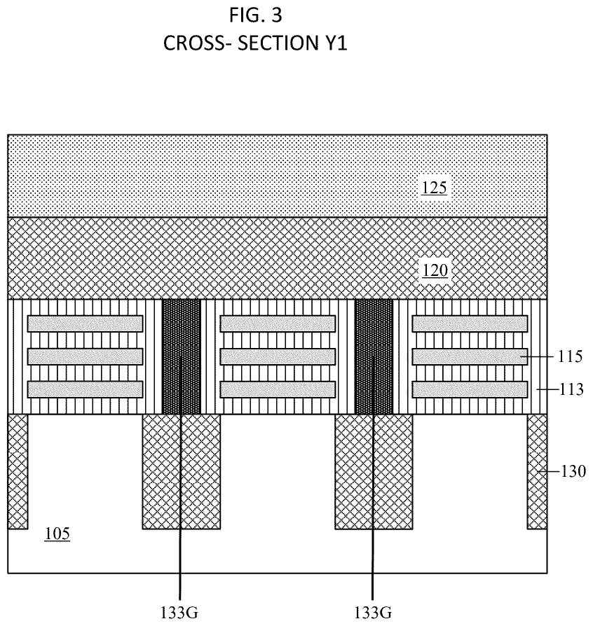

FIG. 3 illustrates the edge of the gate region that extends across multiple adjacent nanosheet transistors. The alternating layers are separated into a plurality of columns to create the adjacent nanosheet transistors. Substrate 105 is etched during this process to create a plurality of trenches (not shown) in substrate 105. Shallow trench isolation layer 130 is formed by filling these trenches with a suitable material. Prior to the formation of the dummy gate 120 and the hardmask 125, additional sacrificial material is added to create a shell around the nanosheet columns. The additional sacrificial material can be the same material as the sacrificial layers 113. The same reference numbers will be used for both and referred as the same layers. A gap (not shown) remains after the additional sacrificial layer 113 material is added, where the gap is located between the nanosheet columns above the shallow trench isolation layer 130. Dielectric pillars 133G, 133SD are formed by filling these gaps in with a dielectric material. The dielectric pillars 133G, 133SD are continuous between the source/drain region (as illustrated by cross-section Y2) and the gate region (as illustrated by cross-section Y1). As seen in FIG. 2 the dummy gate 120 and hardmask 125 are located on top of a portion of the dielectric pillar 133G (reference number 133G will reference the portion of the dielectric pillar located in the gate region).

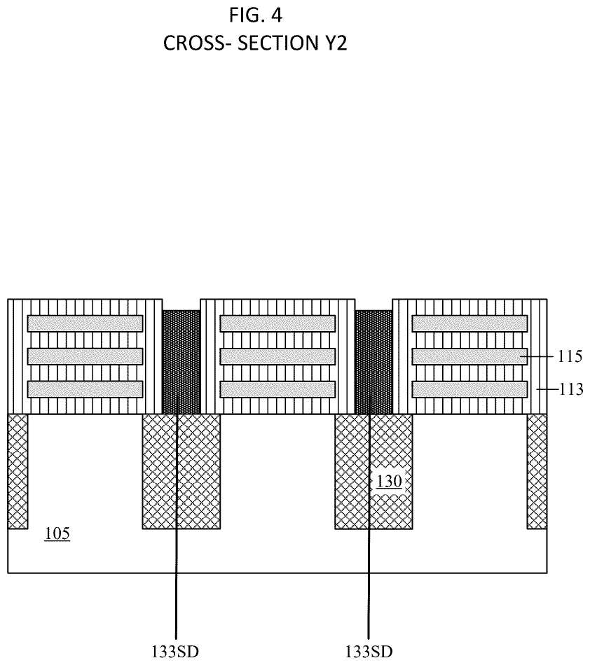

FIG. 4 illustrates the source/drain region after the patterning of the dummy gate 120 and the hardmask 125, and the etch back of the gate spacer 127. The dielectric pillar 133SD (reference number 133SD will reference the portion of the dielectric pillar located in the source/drain region) height is reduced from the different etching processes. The reduction of the height of the dielectric pillar 133SD is unavoidable and causes the sacrificial layer 113 to extend higher than the dielectric pillar 133SD. This causes the variations of the height of the dielectric pillar such that the height of the dielectric pillar 133G in the gate region is greater than the height of the dielectric pillar 133SD I the source/drain region.

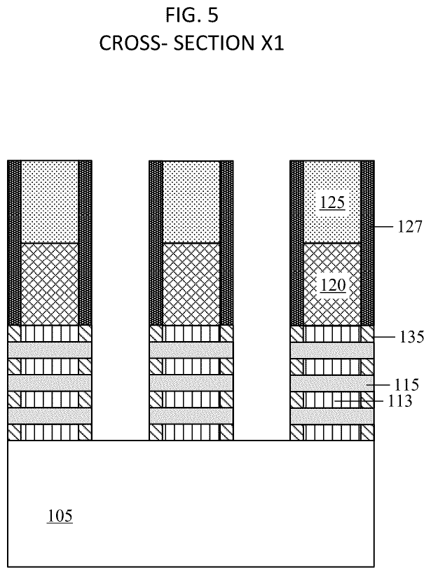

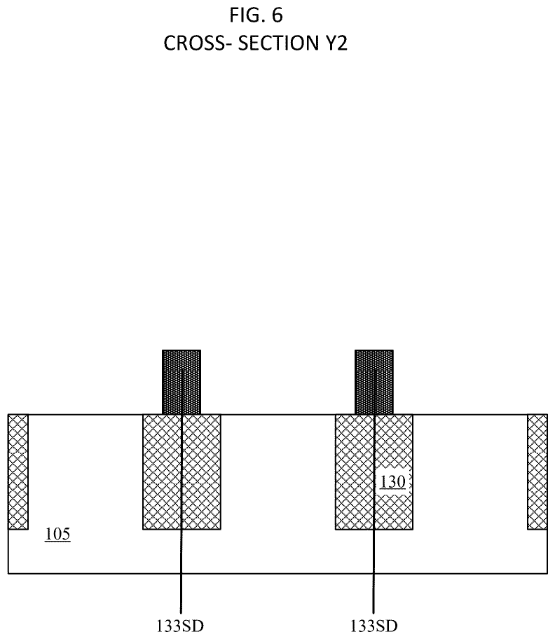

FIGS. 5 and 6 illustrate the processing stage after the formation of nanostacks and an inner spacer 135. The source/drain region is formed by separating the plurality of layer columns into a plurality of nanostacks. Each of the nanostacks are located under dummy gate 120, hardmask 125, gate spacer 127 columns. The source/drain region is located between each of these columns. The sacrificial layers 113 are recessed to create an empty space (not shown) around the channel layers 115 (i.e., the nanosheets). Inner spacer 135 is formed by filling these empty spaces with a suitable material. FIG. 6 illustrates the source/drain region after the plurality of layers are removed. The removal of these layers exposes portions of the shallow trench isolation layer 130 and the substrate 105. The height of the dielectric pillar 133SD is further reduced by the etching process to create the source/drain region. This means that the height difference between the dielectric pillar 133SD (located in the source/drain region) and the dielectric pillar 133G (located in the gate region) is increased.

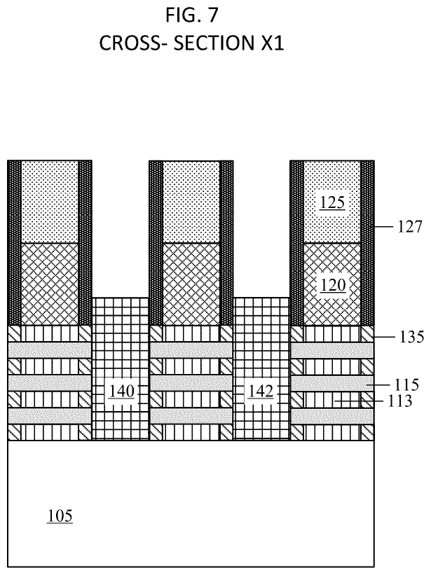

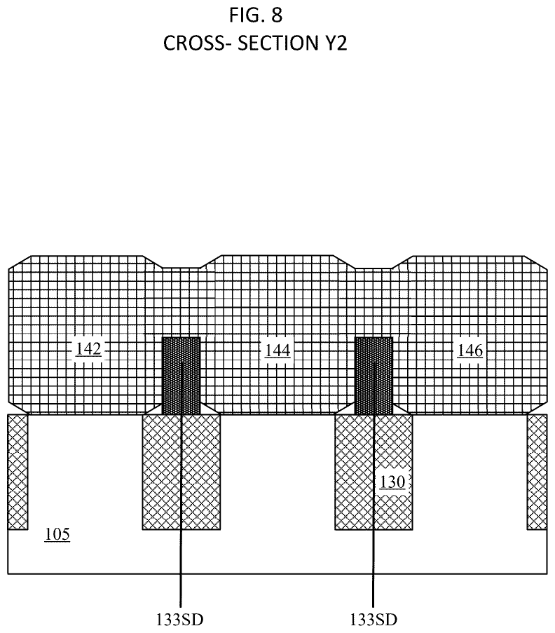

FIGS. 7 and 8 illustrate the processing stage after the formation of source/drains 140, 142, 144, 146. The source/drains 140, 142, 144, 146 are epitaxially grown in the source/drain regions. The source/drains 140, 142, 144, 146, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

As illustrated in FIG. 8, the height of the dielectric pillar 133SD is lower than the height of the adjacent source/drains 142, 144, 146. Specifically, the source/drains 142, 144, 146 growth extends over the dielectric pillars 133SD, such that the source/drains 142, 144, 146 can connect to each other or merge together as illustrated in FIG. 8. Alternatively, the source/drains 142, 144, 146 do not have to connect or merge, but the distance between the adjacent source/drains 142, 144, 146 is reduced enough that an electrical defect can occur. An alternative situation is where a combination of merged and close proximity source/drains 142, 144, 146 occurs. It does not matter of the type of situation or type of scenario because the growth of the source/drains 142, 144, 146 will lead to source/drain material extending over the dielectric pillars 133SD and causing defects.

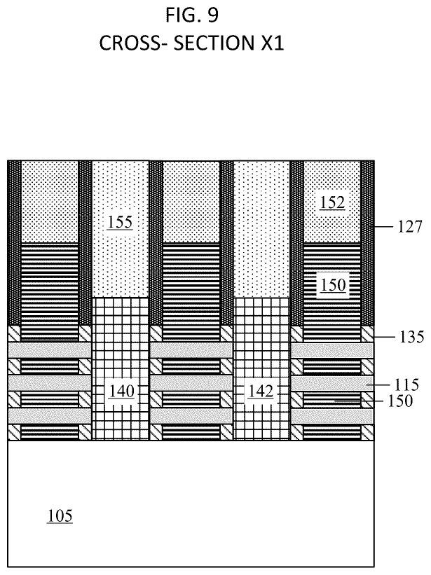

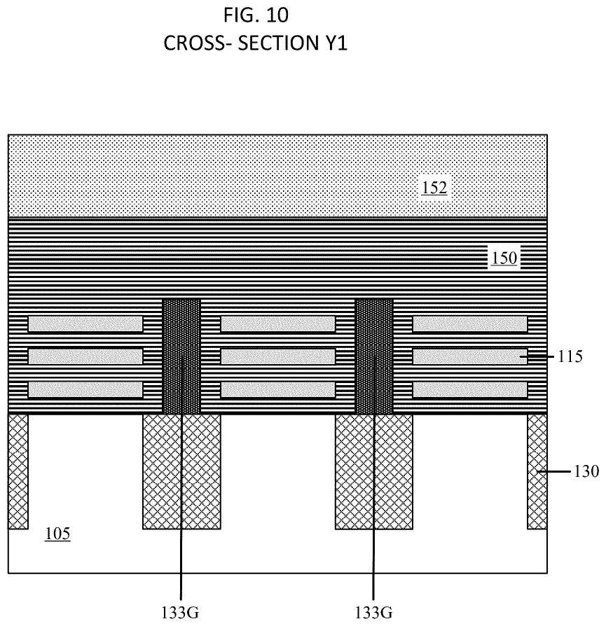

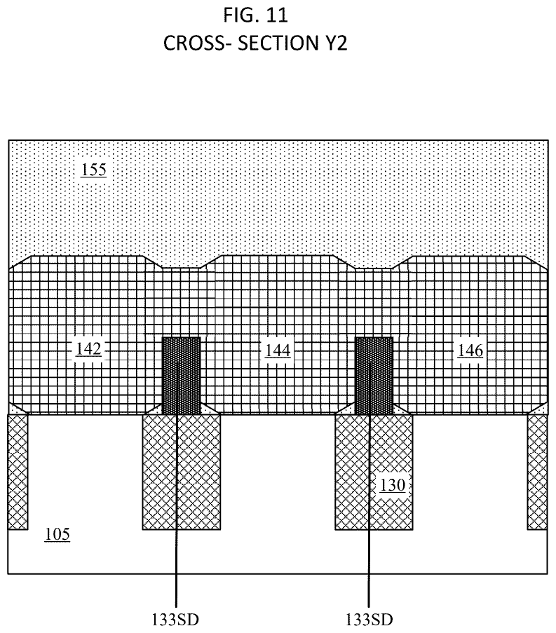

FIGS. 9, 10 and 11 illustrate the processing stage after the formation of the interlayer dielectric layer 155, removal of the dummy gate 120 and the hardmask 125, formation of the gate 150, formation of the gate cap 152. An interlayer dielectric layer 155 is formed on top of the source/drains 140, 142, 144, 146 (see, for example, FIGS. 9 and 11). The hardmask 125, the dummy gate 120, and the sacrificial layers 113 are removed. Gate 150 is formed in the space created by removing these layers. Gate 150 can be comprised of, for example, a gate dielectric liner, such as high-k dielectric like HfO₂, ZrO₂, HfLₐOₓ, etc., and work function layers, such as TIN, TiAlC, TiC, etc., and conductive metal fills, like W. Gate cap 152 is formed on top of gate 150. Gate cap 152 can be comprised of, for example, SiN. As illustrated in FIG. 10, gate 150 is a common gate or a shared gate that extends over multiple nanosheet transistors. Gate 150 extends over dielectric pillar 133G.

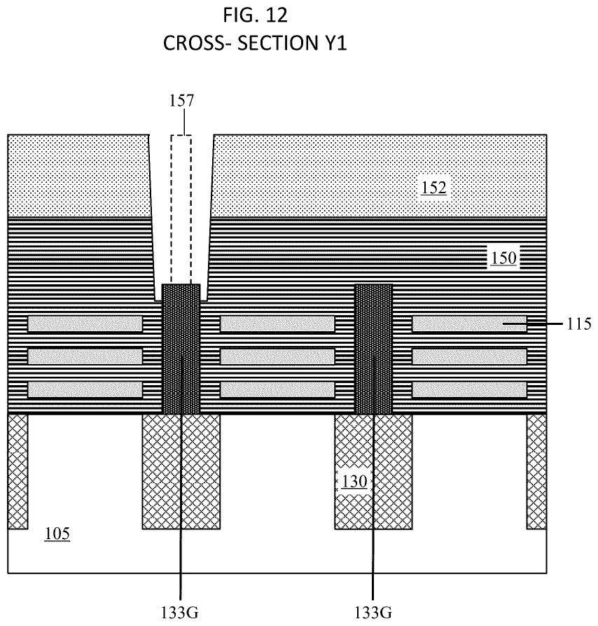

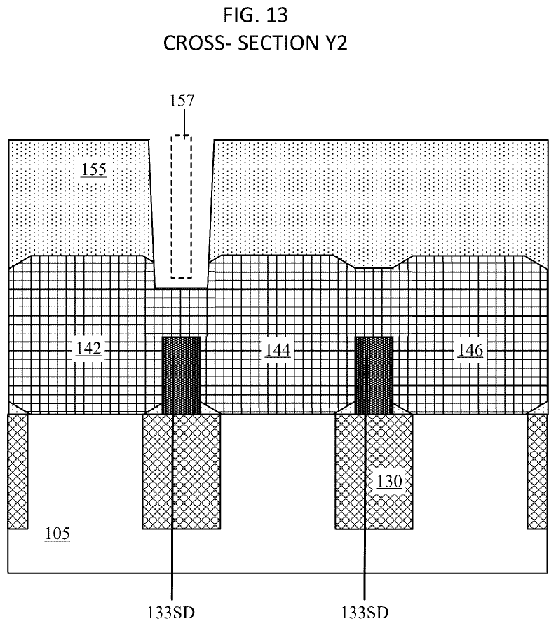

FIGS. 12 and 13 illustrate the processing stage after the first cut step. A lithography layer (not shown) is formed on top of gate cap 152 and the interlayer dielectric layer 155. The lithography layer is patterned and a first cut trench 157 is formed in the gate cap 152, interlayer dielectric layer 155, gate 150, and into the material of the source/drain 142, 144. The lithography layer is removed. The first cut trench 157 can expose a portion of the dielectric pillar 133G (e.g., in the gate region). The first cut trench 157 separates gate 150 material between two adjacent nanosheet transistors as illustrated in FIG. 12. FIG. 12 further illustrates that gate 150 can be shared between two adjacent nanosheet transistors. The first cut trench 157 could separate the nanosheet transistor between single gate 150 devices, shared gate 150 devices, or any combination thereof. As illustrated in FIG. 13 the first cut trench 157 extends into the source/drain material of the merged adjacent source/drain 142, 144. The first cut trench 157 does not separate the adjacent source/drains 142 and 144 since the depth of the first cut trench 157 to achieve full source/drain separation will result in damage to the gate region. The means that extending the first cut trench 157 downwards will lead to the damaging of the gate 150 and channel layers 115.

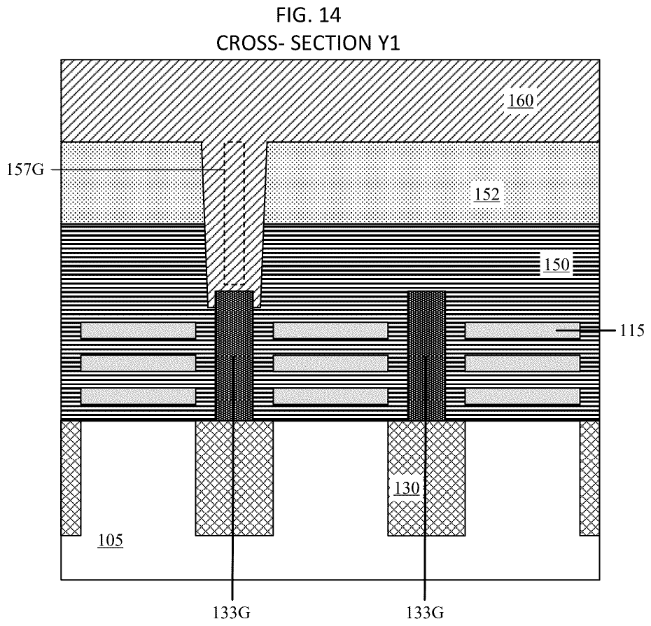

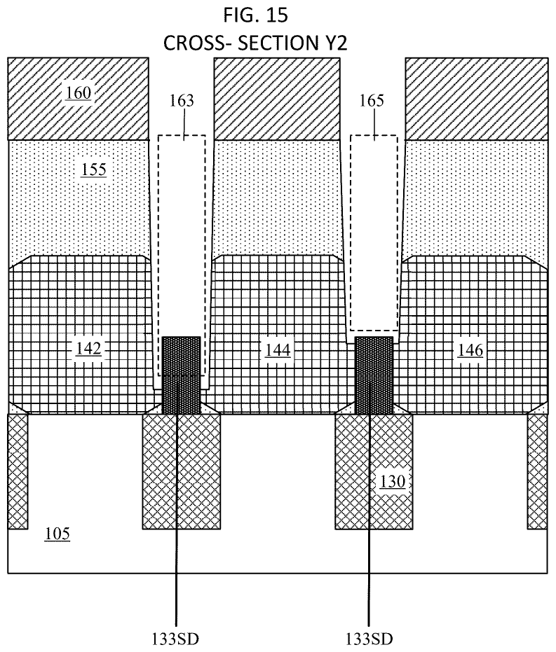

FIGS. 14 and 15 illustrate the processing stage after formation of a second lithography layer 160 and patterning of the second cut trenches 163 and 165. A second lithography layer 160 is formed on top of the exposed surfaces and the second lithography layer 160 fills the first cut trench 157. The second lithography layer 160 is patterned but a portion of the material remains within the first cut trench 157, herein after using the reference number 157G, located in the gate region. The second lithography layer 160 prevents an increase of the depth of the first cut trench 157G in the gate region. A plurality of second cut trenches 163, 165 are formed in the source/drain region. Second cut trench A 163 is an extension of the first cut trench 157 in the source/drain region, meaning the depth of the first cut trench 157 is increased to form the second cut trench A 163. Second cut trench A 163 extends downwards to expose the dielectric pillar 133SD located between the source/drains 142, 144, therefore second cut trench A 163 separates the adjacent source/drains 142, 144. Second cut trench B 165 extends downwards through the interlayer dielectric layer 155 and the source/drains 144, 146 to expose the dielectric pillar 133SD. The second cut trench B 165 does not extend as deep as the second cut trench A 163, another way of saying it is that second cut trench A 163 depth/height is greater than the second cut trench B 165. The difference of the depth/height of the second cut trenches A, B 163, 165 can be contributed to the portion of the first cut trench 157 located in the source/drain region. This means the etching process to form the second cut trenches A, B 163, 165 did not start at the same height. Therefore, the etch time needed for the second cut trench B 165 to reach the dielectric pillar 133SD will result in the second cut trench A 163 to have etched to a lower depth than that of second cut trench B 165.

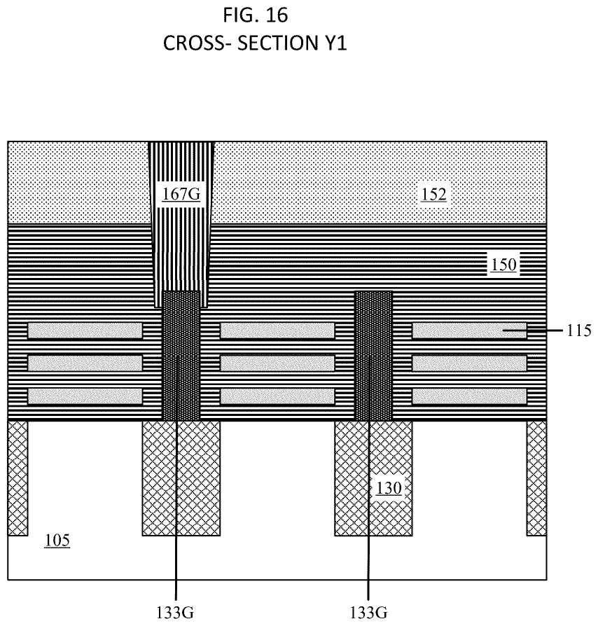

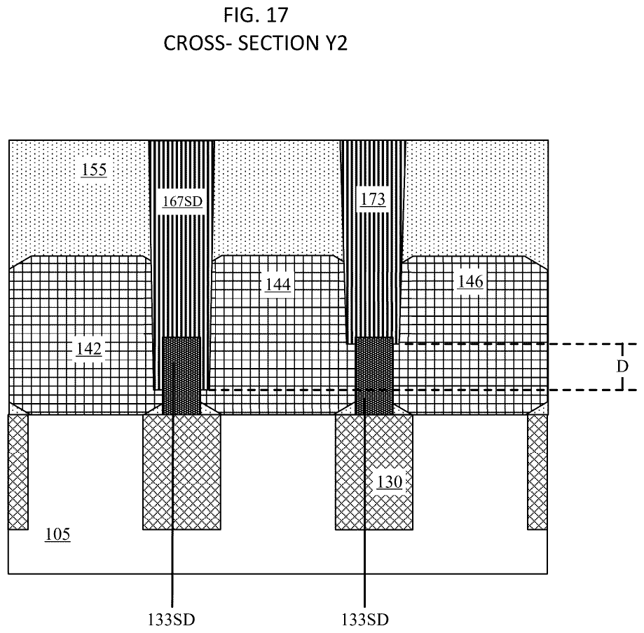

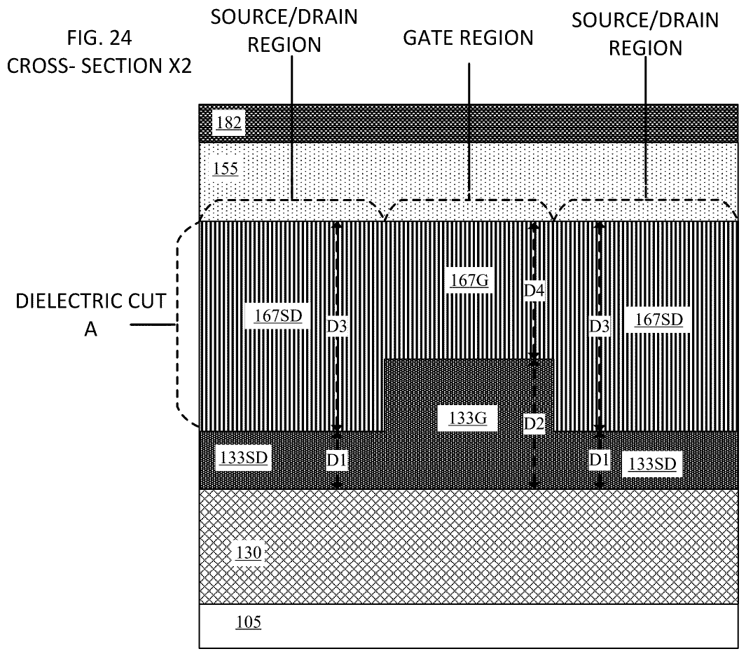

FIGS. 16 and 17 illustrate the processing stage after formation of the dielectric cuts 167G, 167SD, 173. The second lithography layer 160 is removed which exposes the first cut trench 157G which is connected to the second cut trench A 163. Dielectric cuts 167G, 167SD, 173 are formed by filling the first cut trench 157G, the second cut trench A 163, and the second cut trench B 165 with a dielectric material. The dielectric cuts 167G, 167SD and 173 are continuous between the source/drain region (as illustrated by cross-section Y2) and the gate region (as illustrated by cross-section Y1). Dielectric cut 167G refers to a section of the dielectric cut A located in the gate region and dielectric cut 167SD refers to a section of the same dielectric cut A located in the source/drain region. Dielectric cut 167G is connected to dielectric pillar 133G and dielectric cut 167SD is connected to the dielectric pillar 133SD. FIG. 24 illustrates the dielectric cut A as it extends through the source/drain region and the gate region, which will be described in further detail below. Dielectric cut 173 is connected to the dielectric pillar 133SD located between source/drains 144, 146. As illustrated in FIG. 17, difference D represents the differences in the depths of the dielectric cuts 167SD and 173 in the source/drain region. Difference D occurs when the dielectric cuts 167G and 167SD (or dielectric cut A) is formed as one continues cut. The dielectric pillars 133SD, 133G and the dielectric cuts 167SD, 167G can be comprised of the different or the same dielectric material.

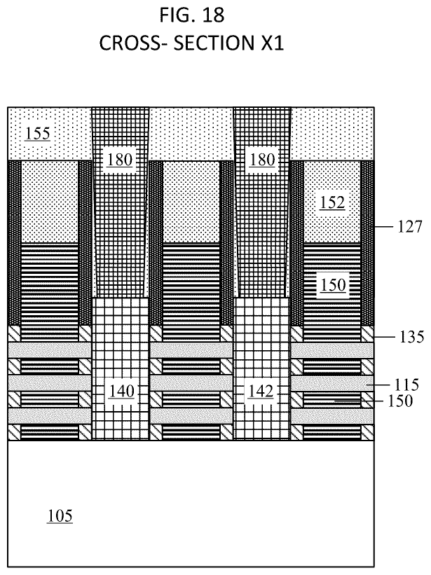

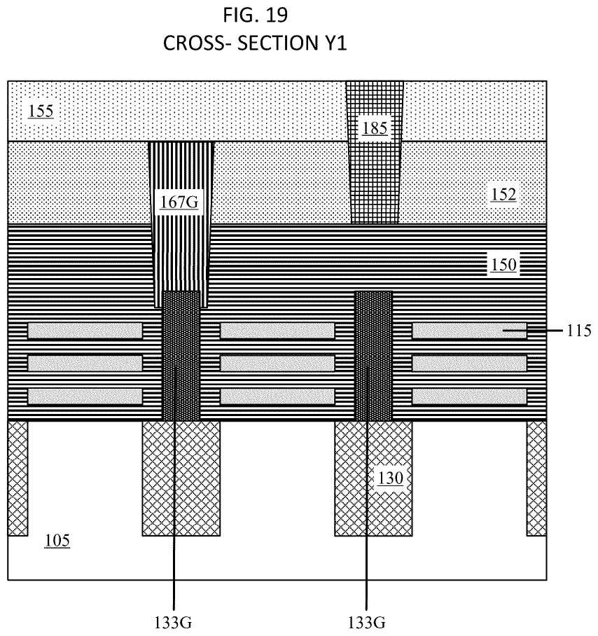

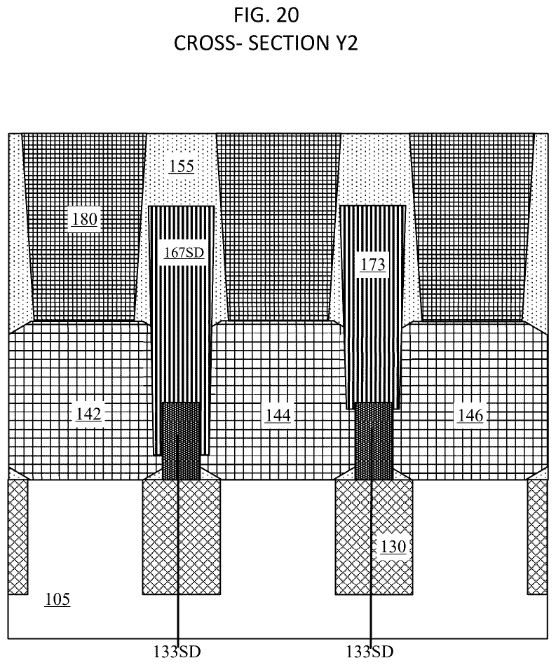

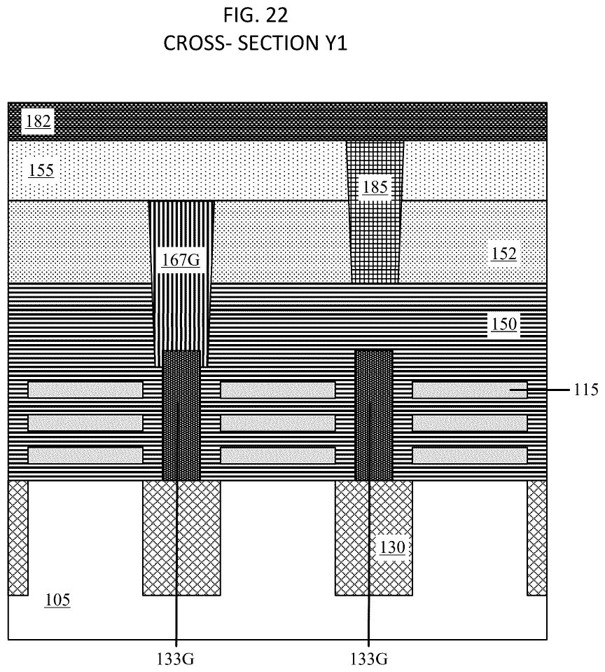

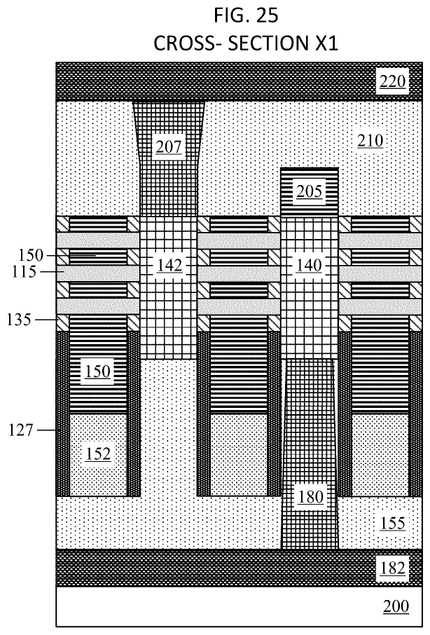

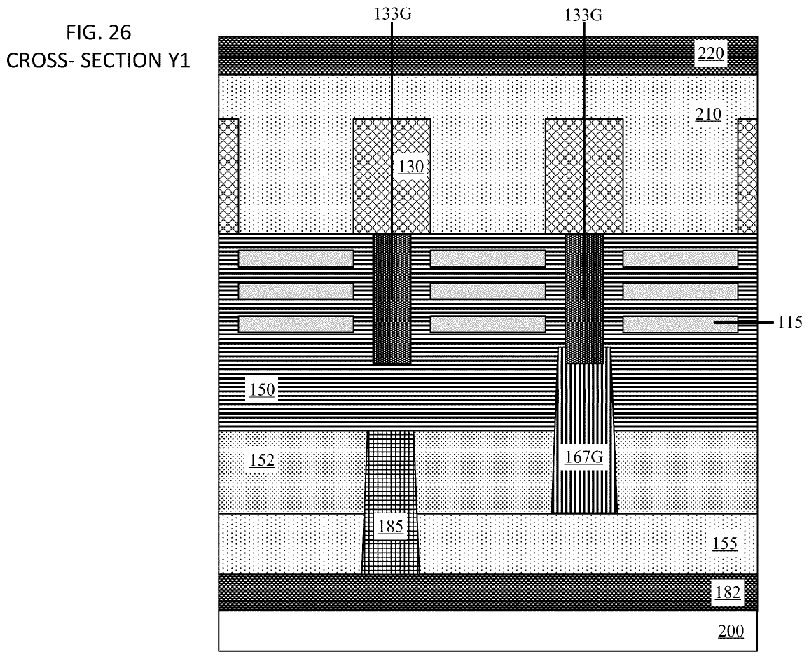

FIGS. 18, 19 and 20 illustrate the processing stage after increasing the height of the interlayer dielectric layer 155 and the formation of source/drain contacts 180 and gate contact 185. Additional interlayer dielectric material is added to increase the height of the interlayer dielectric layer 155 so that the interlayer dielectric layer 155 extends on top of the gate cap 152 and on top of the dielectric cuts 167G, 167SD, 173. Trenches (not shown) are formed in the interlayer dielectric layer 155 and the gate cap 152. These trenches are filled in with a conductive material to form gate contact 185 and frontside source/drain contacts 180. FIGS. 19-24 only illustrate the formation of frontside contacts 180, but the present invention is not limited to only frontside contacts 180. FIGS. 25-27 illustrate the use of backside source/drain contacts 207 in accordance with the present invention, which will be described in further detail below. The Figures only illustrate the formation of one gate contact 185 (e.g., the shared gate contact 185 connected to the shared gate 150 as illustrated in FIG. 19). This is meant for example purpose only; it is well within the skill level of one of ordinary skill in the art to realize that a plurality of gate contacts 185 can or are formed and that each of the gate contacts 185 is connected to a single gate 150 or a shared gate 150.

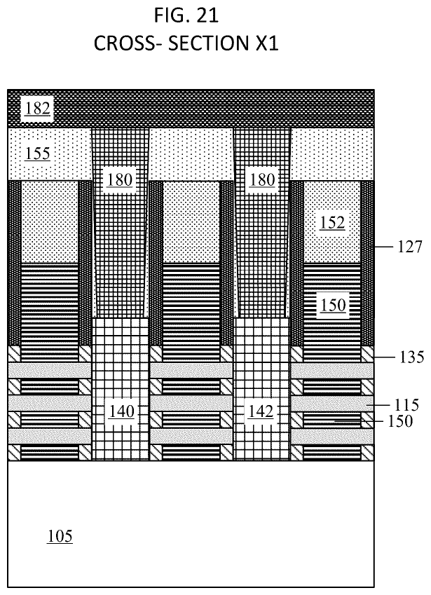

FIGS. 21, 22, 23 and 24 illustrate the processing stage after formation of the back-end-of-line (BEOL) layer 182. A back-end-of-the-line (BEOL) layer 182 is formed on top of the interlayer dielectric layer 155, on top of the frontside contacts 180, and on top of the gate contact 185. The BEOL layer 182 can be comprised of one or more layers, one or more electrical lines, and one or more connection vias to connect to the frontside source/drain contacts 180 and the gate contacts 185. FIG. 24 illustrates a cross-section through dielectric cut A, which illustrates the profile of the dielectric pillar 133SD, 133G and the profile of the dielectric cut 167SD, 167G as they extend across the source/drain regions and the gate region. FIG. 24 illustrates a cross-section that is perpendicular to the gate direction and in parallel to the nanosheet transistors. Dielectric pillar 133SD, 133G is a continues dielectric pillar that has a different height in the different regions. Dielectric pillar 133SD has a first dimension D1 or height D1 in the source/drain region and the dielectric pillar 133G has a second dimension D2 or second height D2 in the gate region. Second dimension D2 is greater than the first dimension D1, where the difference of the dimension was caused by the processing of the source/drain region. This means that the height of the dielectric pillar 133G, 133SD varies between the regions (i.e., the gate region and the source/drain region). Dielectric pillar 133SD, 133G forms a unique profile as viewed from cross-section X2 (as illustrated in FIG. 24), such that dielectric pillar 133G looks like a protrusion/bump/mountain/hill/elevation that extends from the dielectric pillar 133SD. The unique profile of the dielectric pillar 133SD, 133G affects the profile of dielectric cut 167SD, 167G. Dielectric cut 167SD has a third dimension D3 or height D3 in the source/drain region and the dielectric cut 167G has a fourth dimension D4 or height D4 in the gate region. Third dimension D3 is greater than the fourth dimension D4, since the first dimension D1 is less than the second dimension D2. This means that the height of the dielectric cut 167G, 167SD varies between the regions (i.e., the gate region and the source/drain region). The profile of the dielectric cut 167SD, 167G has a recess/valley in the gate region such that the protrusion of the dielectric pillar 133G fits in the recess of the dielectric cut 167SD, 167G. The combined or sum of the first dimension D1 and the third dimension D3 should be equal to the combined or sum of the second dimension D2 and the fourth dimension D4.

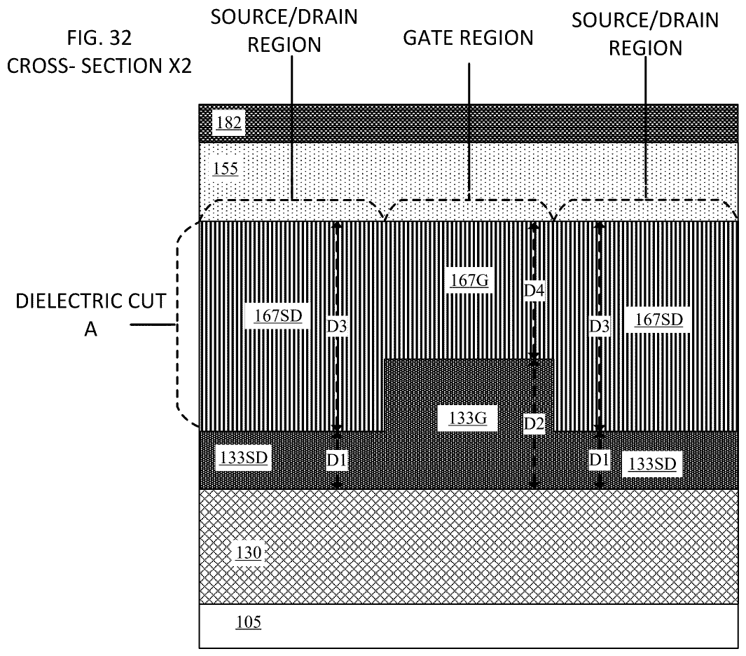

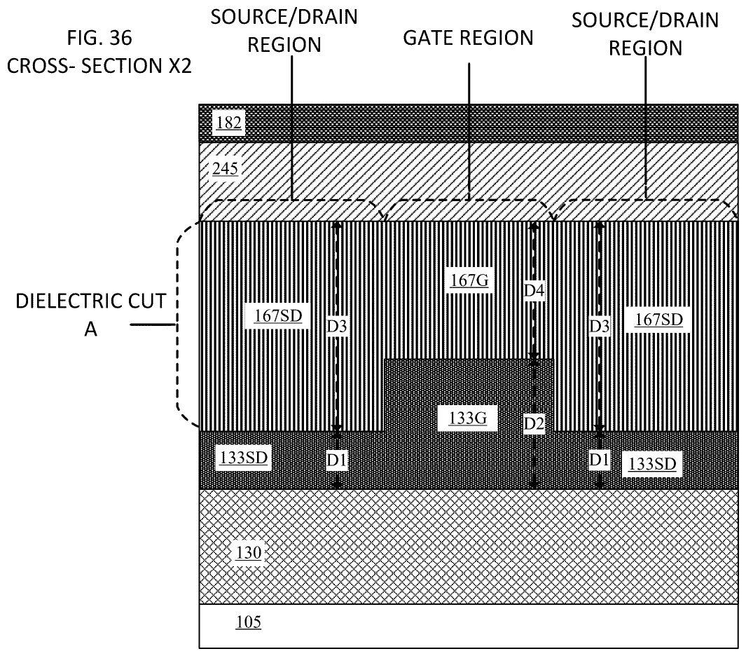

The figures illustrate an example of a field-effect-transistor, for example, a nanosheet transistor, but the present invention is not limited to only nanosheet transistors. The present invention is directed where the dielectric cut 167G, 167SD is continuous between the source/drain region and the gate region as illustrated in FIGS. 24, 28, 32, and 36

A microelectronic structure that includes a first field-effect-transistor and a second field-effect-transistor. The first field-effect-transistor is directly adjacent to the second field-effect-transistor along the gate direction, where the first field-effect-transistor includes a first source/drain 142 and the second field-effect-transistor includes a second source/drain 144. A dielectric pillar 133SD, 133G is located between the first field-effect-transistor and the second field-effect-transistor. The dielectric pillar 133G, 133SD is a continuous structure between a source/drain region and an adjacent gate region. A height D1, D3 of the dielectric pillar 133SD, 133G varies between the gate region and the source/drain region located between the first field-effect-transistor and the second field-effect-transistor. A dielectric cut 167G, 167SD connected to the dielectric pillar 133SD, 133G.

A height of the dielectric cut 167G, 167SD varies between the gate region and the source/drain region.

The dielectric pillar 133SD has a first height D1 in the source/drain region and the dielectric pillar 133G has a second height D2 in the gate region. The first height D1 is less than the second height D2. A height D3, D4 of the dielectric cut 167SD, 167G varies between the gate region and the source/drain region. The dielectric cut 167SD has a third height D3 in the source/drain region and the dielectric pillar 167G has a fourth height D4 in the gate region. The fourth height D4 is less than the third height D3. The first height D1 of the dielectric pillar 133SD and the third height D3 of the dielectric cut 167SD form a first combined height. The second height D2 of the dielectric pillar 133G and the fourth height D4 of the dielectric cut 167G form a second combined height. The first combined height is substantially equal to the second combined height.

A microelectronic structure includes a first field-effect-transistor and a second field-effect-transistor. The first field-effect-transistor is directly adjacent to the second field-effect-transistor along the gate direction. The first field-effect-transistor includes a first source/drain 142 and the second field-effect-transistor includes a second source/drain 144. A dielectric pillar 133SD, 133G located between the first field-effect-transistor and the second field-effect-transistor. The dielectric pillar 133SD, 133G includes a protrusion 133G located in a gate region and a lower plateau 133SD located in a source/drain region, such that a height of the protrusion 133G and a height of the lower plateau 133SD are different. A dielectric cut 167SD, 167G connected to the dielectric pillar 133SD, 133G. The dielectric cut 167SD, 167G includes a valley to wrap around the dielectric pillar protrusion 133G.

The dielectric pillar lower plateau 133SD has a first height D1 in the source/drain region and the dielectric pillar protrusion 133G has a second height D2 in the gate region. The first height D1 is less than the second height D2. A height of the dielectric cut 167SD, 167G varies between the gate region and the source/drain region. The dielectric cut 167SD has a third height D3 in the source/drain region and the dielectric pillar 133G has a fourth height D4 in the gate region. The fourth height D4 is less than the third height D3. The first height D1 of the dielectric pillar lower plateau 133SD and the third height D3 of the dielectric cut 167SD form a first combined height. The second height D2 of the dielectric pillar protrusion 133G and the fourth height D4 of the dielectric cut 167G form a second combined height. The first combined height is substantially equal to the second combined height.

A method includes the steps of forming a first nanosheet transistor and a second nanosheet transistor. The first nanosheet transistor is directly adjacent to the second nanosheet transistor along the gate direction, where the first nanosheet transistor includes a first source/drain 142 and the second nanosheet transistor includes a second source/drain 144. Forming a dielectric pillar 133SD, 133G is located between the first nanosheet transistor and the second nanosheet transistor. The dielectric pillar 133G, 133SD is a continuous structure between a source/drain region and an adjacent gate region. A height D1, D3 of the dielectric pillar 133SD, 133G varies between a gate region and a source/drain region located between the first nanosheet transistor and the second nanosheet transistor. The height differences of the dielectric pillar 133SD, 133G are caused by the processing of the source/drain region. Forming dielectric cut 167G, 167SD connected to the dielectric pillar 133SD, 133G.

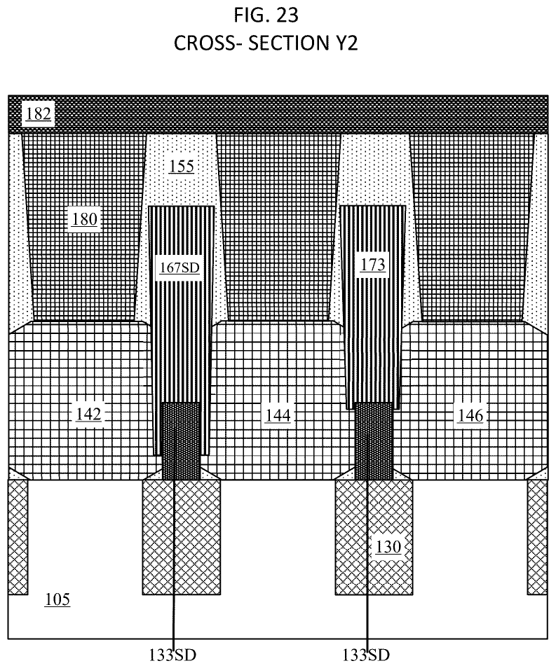

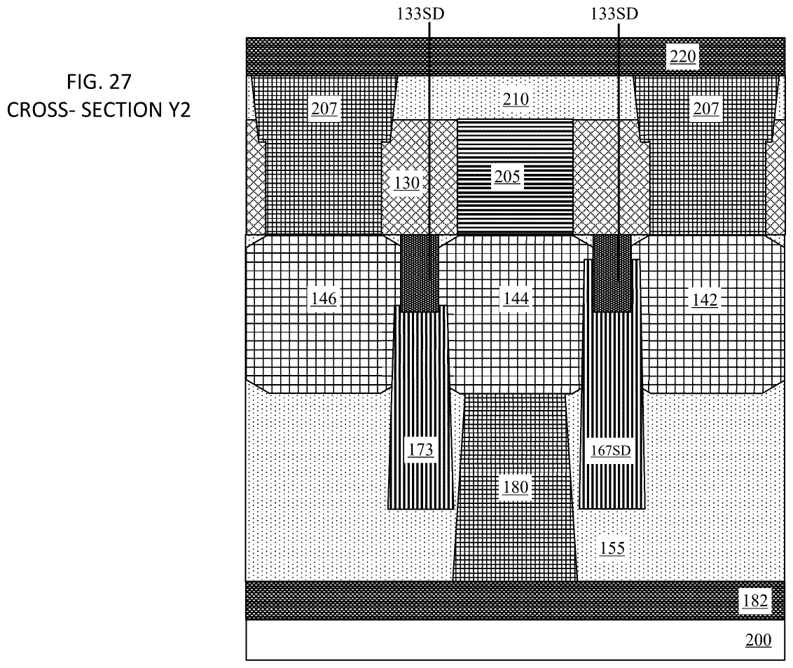

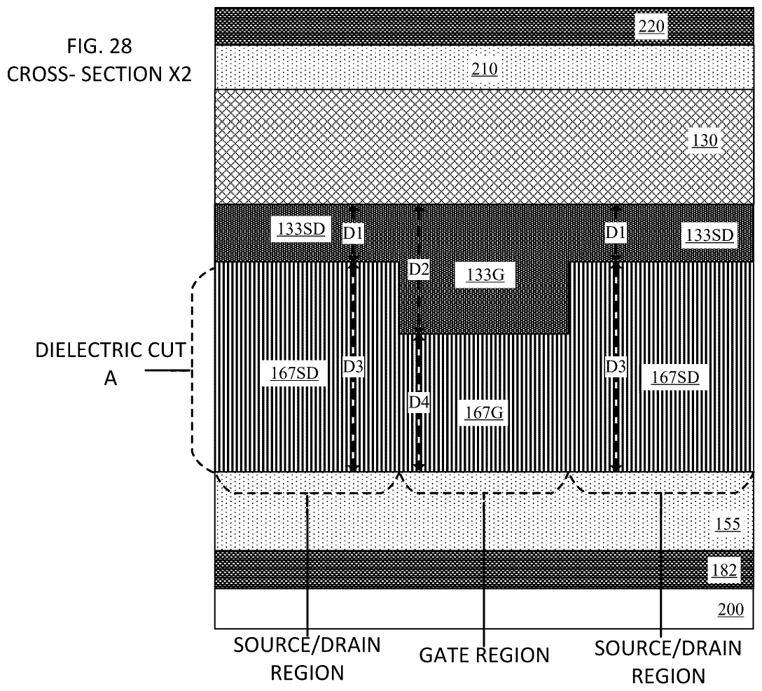

FIGS. 25, 26, 27 and 28 illustrate the processing stage after formation of the backside-power-distribution-network 220. FIGS. 25-27 is a nanosheet transistor that has a similar structure as the nanosheet transistor illustrated in FIGS. 21-24, but instead of having only frontside contacts 180, the backside of the nanosheet transistor is processed to form backside components. Prior to the formation of the source/drains 140, 142, 144, 146 a place holder 205 is formed within substrate 105, such that the placeholders are located between sections of the shallow trench isolation layer 130. Carrier wafer 200 is attached to the BEOL layer 182, where the carrier wafer 200 allows for the wafer containing the nanosheet transistor to be flipped over for backside processing. The nanosheet is flipped over exposing substrate 105 for backside processing. Substrate 105 is removed and a backside interlayer dielectric layer 210 is formed. Trenches (not shown) are formed in the backside interlayer dielectric layer 210 to expose some of the placeholders 205. Placeholders 205 are removed to expose a backside surface of some of the source/drains 142, 146. Backside contacts 207 are formed by filling these exposed trenches with a conductive metal. Backside-power-distribution-network (BSPDN) 220 is formed on top of the backside interlayer dielectric layer 210 and backside contacts 207. A difference between FIGS. 23 and 27 is that some of the frontside contacts 180 have been replaced with backside contacts 207. FIG. 28 illustrates the inverted profile of the dielectric cut 167SD, 167G and the dielectric pillar 133SD, 133G when compared to the profile as illustrated in FIG. 24.

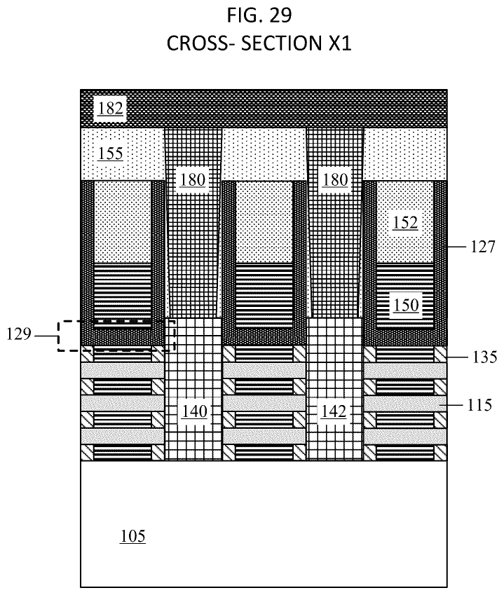

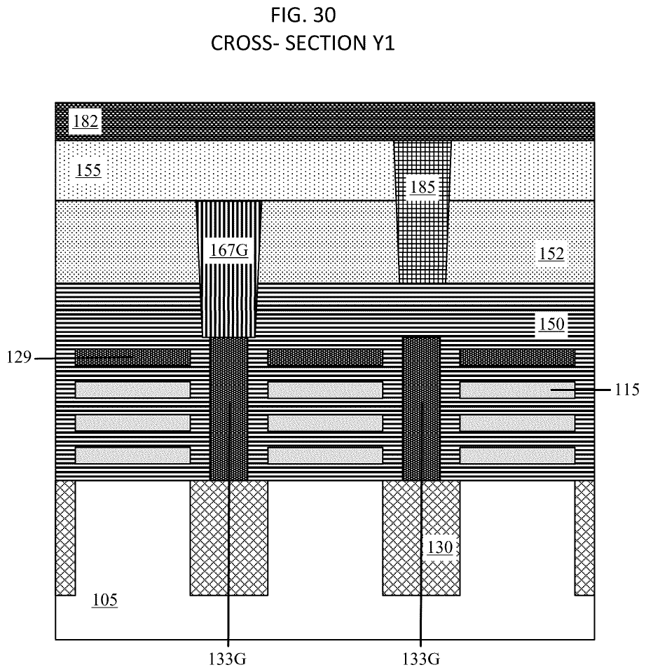

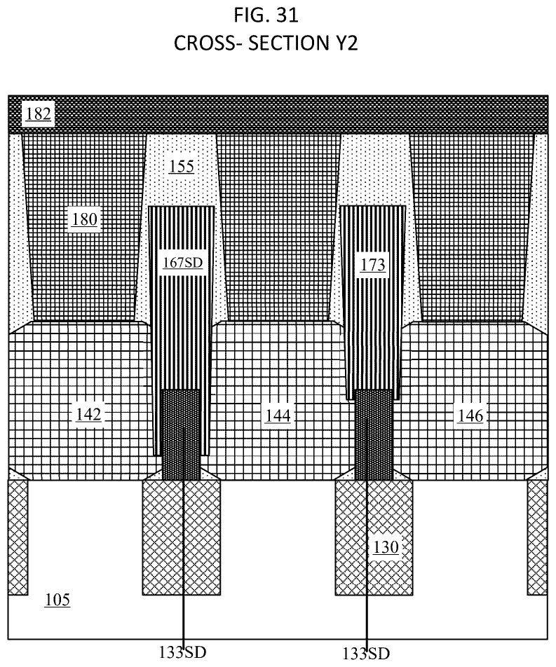

FIGS. 29, 30, 31 and 32 illustrate the processing stage after formation of the back-end-of-line (BEOL) layer 182. The nanosheet transistor shown in FIG. 29-32 is similar to the nanosheet transistor shown in FIGS. 21-24. The difference in the structure is illustrated in FIGS. 29 and 30, where the gate spacer 127 has horizontal section, as emphasized by dashed box 129, that extends between the vertical sections of the gate spacer 127. The horizontal section 129 is located within gate 150, such that gate 150 surrounds the horizontal section 129, as illustrated in FIG. 30. The addition of horizontal section 129 can lead to an increase in the height of nanosheet transistor, such that the height/dimensions of the dielectric pillar 133SD, 133G sections will be different than those of the first embodiment.

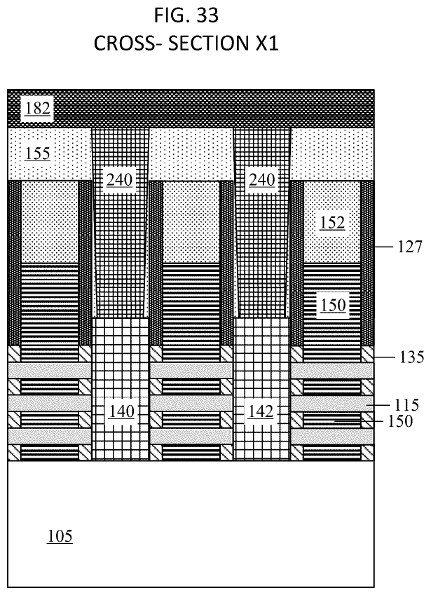

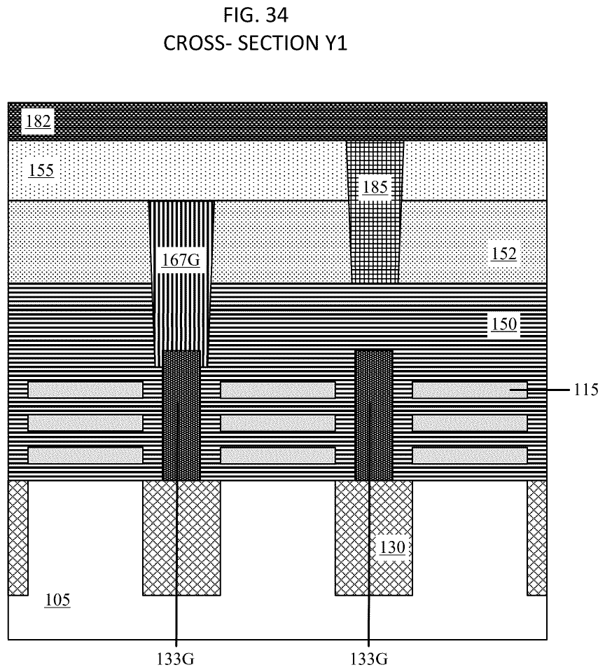

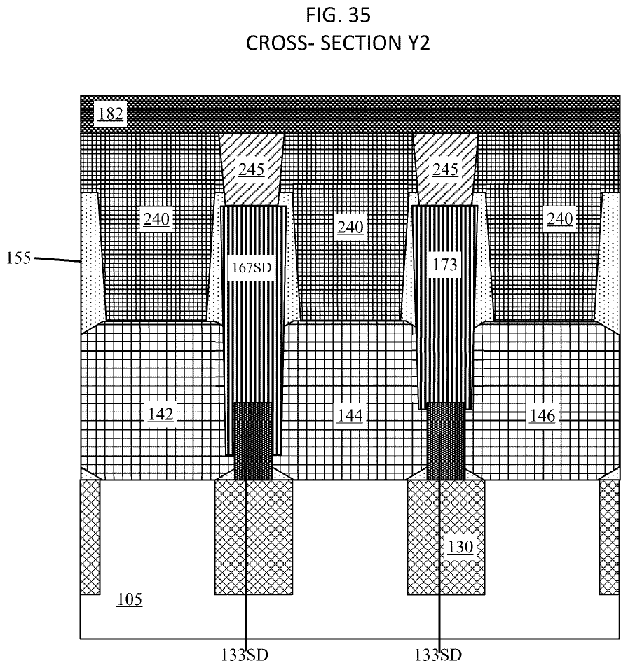

FIGS. 33, 34, 35 and 36 illustrate the processing stage after formation of the back-end-of-line (BEOL) layer 182. The nanosheet transistor shown in FIG. 33-34 is similar to the nanosheet transistor shown in FIGS. 21-24. The difference between the figures is that the frontside contact 180 was replaced with a shared frontside contact that was separated into a plurality of separated contacts 240. After the shared frontside contact is formed than a plurality of trenches are formed in the shared contact, where the plurality of trenches align with the dielectric cuts 167SD, 173. Source/drain contact cut 245 is formed by filling these trenches in with a suitable dielectric material that isolate each of the separated contacts 240.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first field-effect-transistor and a second field-effect-transistor, wherein the first field-effect-transistor is directly adjacent to the second field-effect-transistor along a gate direction, wherein the first field-effect-transistor includes a first source/drain and the second field-effect-transistor includes a second source/drain;
a dielectric pillar located between the first field-effect-transistor and the second field-effect-transistor, wherein the dielectric pillar is a continuous structure between a source/drain region and an adjacent gate region, wherein a height of the dielectric pillar varies between the gate region and the source/drain region located between the first field-effect-transistor and the second field-effect-transistor; and
a dielectric cut connected to the dielectric pillar.

2. The microelectronic structure of claim 1, wherein a height of the dielectric cut varies between the gate region and the source/drain region.

3. The microelectronic structure of claim 1, wherein the dielectric pillar has a first height in the source/drain region and the dielectric pillar has a second height in the gate region.

4. The microelectronic structure of claim 3, wherein the first height is less than the second height.

5. The microelectronic structure of claim 4, wherein a height of the dielectric cut varies between the gate region and the source/drain region.

6. The microelectronic structure of claim 5, wherein the dielectric cut has a third height in the source/drain region and the dielectric pillar has a fourth height in the gate region.

7. The microelectronic structure of claim 6, wherein the fourth height is less than the third height.

8. The microelectronic structure of claim 7, wherein the first height of the dielectric pillar and the third height of the dielectric cut form a first combined height.

9. The microelectronic structure of claim 8, wherein the second height of the dielectric pillar and the fourth height of the dielectric cut form a second combined height.

10. The microelectronic structure of claim 9, wherein the first combined height is substantially equal to the second combined height.

11. A microelectronic structure comprising:
a first nanosheet transistor and a second nanosheet transistor, wherein the first nanosheet transistor is directly adjacent to the second nanosheet transistor along a gate direction, wherein the first nanosheet transistor includes a first source/drain and the second nanosheet transistor includes a second source/drain;
a dielectric pillar located between the first nanosheet transistor and the second nanosheet transistor, wherein the dielectric pillar includes a protrusion located in a gate region and a lower plateau located in a source/drain region, such that a height of the protrusion and a height of the lower plateau are different; and
a dielectric cut connected to the dielectric pillar, wherein the dielectric cut includes a valley to wrap around the dielectric pillar protrusion.

12. The microelectronic structure of claim 11, wherein the dielectric pillar lower plateau has a first height in the source/drain region and the dielectric pillar protrusion has a second height in the gate region.

13. The microelectronic structure of claim 12, wherein the first height is less than the second height.

14. The microelectronic structure of claim 13, wherein a height of the dielectric cut varies between the gate region and the source/drain region.

15. The microelectronic structure of claim 14, wherein the dielectric cut has a third height in the source/drain region and the dielectric pillar has a fourth height in the gate region.

16. The microelectronic structure of claim 15 wherein the fourth height is less than the third height.

17. The microelectronic structure of claim 16, wherein the first height of the dielectric pillar lower plateau and the third height of the dielectric cut form a first combined height.

18. The microelectronic structure of claim 17, wherein the second height of the dielectric pillar protrusion and the fourth height of the dielectric cut form a second combined height.

19. The microelectronic structure of claim 18, wherein the first combined height is substantially equal to the second combined height.

20. A method comprising:
forming a first field-effect-transistor and a second field-effect-transistor, wherein the first field-effect-transistor is directly adjacent to the second field-effect-transistor along a gate direction, wherein the first field-effect-transistor includes a first source/drain and the second field-effect-transistor includes a second source/drain;
forming a dielectric pillar located between the first field-effect-transistor and the second field-effect-transistor, wherein the dielectric pillar is a continuous structure between a source/drain region and an adjacent gate region, wherein the height of the dielectric pillar varies between the gate region and the source/drain region located between the first field-effect-transistor and the second field-effect-transistor, wherein the height differences of the dielectric pillar are caused by the processing of the source/drain region; and
forming a dielectric cut connected to the dielectric pillar.
